(19) United States
(12) Patent Application Publication
(10) Pub. No.: US 2009/0011574 A1
(43) Pub. Date: Jan. 8, 2009

(54) Method for surface modification of semiconductor layer and method of manufacturing semiconductor device

(75) Inventors: Wei-Yao Tang, Chiayi (TW); Chia-Wei Wu, Hsinchu (TW)

Correspondence Address: BACON & THOMAS, PLLC, 625 SLATERS LANE, FOURTH FLOOR, ALEXANDRIA, VA, 22314-1176, US

(73) Assignee: Macronix International Co., Ltd., Hsinchu (TW)

(21) Appl. No.: 11/822,076

(22) Filed: Jul. 2, 2007

(51) Int. Cl. H01L 21/20; C23G 1/02

(52) U.S. Cl. 438/479; 134/2; 134/3; 257/E21.121

(57) ABSTRACT

A method for surface modification of a semiconductor layer and a method of manufacturing a semiconductor device are provided. The method for surface modification of the silicon layer includes following steps. First, a semiconductor layer having several particles on its surface is provided. Next, these particles are removed through a clean process. In the clean process, the semiconductor layer is exposed to an organic matter remover, a first peroxide mixture solution and a second peroxide mixture solution sequentially.

### BACKGROUND OF THE INVENTION

1. Field of the Invention

The invention relates in general to a method for surface modification of a semiconductor layer and a method of manufacturing a semiconductor device, and more particularly to a method for surface modification of a semiconductor layer by removing particles on the semiconductor layer and a method of manufacturing a semiconductor device.

2. Description of the Related Art

As the semiconductor industry develops vigorously, the semiconductor technology is widely applied to all kinds of electronic devices, such as memories in personal computers, sensing chips in digital cameras and thin-film transistors in liquid crystal display panels. The progress in the semiconductor technology has played an important role in the development of modern technology.

Generally speaking, one common application of the semiconductor device is a metal oxide semiconductor (MOS) transistor. The MOS transistor is formed by stacking a metal layer, an oxide layer and a semiconductor layer having different thickness. The semiconductor layer is generally made of silicon, and the oxide layer is generally made of silicon dioxide (SiO₂). The oxide layer is applied as insulation due to its high dielectric characteristic. Furthermore, the metal layer is generally made of polysilicon for being an electrode layer of the transistor, and a dopant is added into the polysilicon material through doping technology for increasing the conductivity. In one example of the manufacturing process of the semiconductor device, an in-situ doped polysilicon layer is applied for doping the dopant into the polysilicon material. The dopant is driven into the polysilicon material of the electrode layer through a high temperature diffusion doping process for example.

However, after the in-situ doped polysilicon layer is deposited, particles are separated out on the surface of the in-situ doped polysilicon layer due to light, heat or other factors. Please refer to FIGS. 1A˜1D at the same time. FIG. 1A illustrates particle distribution on the surface of the in-situ doped layer after this layer is deposited for 4 hours. FIG. 1B illustrates particle distribution on the surface of the in-situ doped layer after this layer is deposited for 8 hours. FIG. 1C illustrates particle distribution on the surface of the in-situ doped layer after this layer is deposited for 24 hours. FIG. 1D illustrates particle distribution on the surface of the in-situ doped layer after this layer is deposited for 48 hours. As shown in FIGS. 1A˜1D, the number of the particles 111 increases with time. The particles 111 results in various particle issues, such as lowering the surface quality and degrading the electrical properties of the electrode layer. Moreover, the single-bit error rate is raised. Then the operation quality and the reliability of the MOS transistor are lowered accordingly. Furthermore, the yield rate of the MOS transistor is affected, and the manufacturing cost is increased relatively.

### SUMMARY OF THE INVENTION

The invention is directed to a method for surface modification of a semiconductor layer and a method of manufacturing a semiconductor device. Particles on the surface of the semiconductor layer are removed through a clean process, and the surface of the semiconductor layer remains clean for a certain period of time. The method for surface modification of a semiconductor layer and the method of manufacturing a semiconductor device have advantages including increasing yield rate, reducing cost, improving product reliability and simple process steps.

According to the present invention, a method for surface modification of a semiconductor layer is provided. First, a semiconductor layer is provided. There are several particles situated on the surface of the semiconductor layer. Next, the particles are removed through a clean process. The process includes following steps. First, the semiconductor layer is exposed to an organic matter remover. Then, the semiconductor layer is exposed to a first peroxide mixture solution and a second peroxide mixture solution sequentially.

According to the present invention, a method of manufacturing a semiconductor device is provided. First, a substrate is provided. Next, an insulation layer is formed over the substrate. Then, a semiconductor layer is formed on the insulation layer. There are several particles situated on the surface of the semiconductor layer. Afterwards, the particles are removed through a clean process. In the clean process, the semiconductor layer is exposed to an organic matter remover, a first peroxide mixture solution and a second peroxide mixture solution orderly.

The invention will become apparent from the following detailed description of the preferred but non-limiting embodiment. The following description is made with reference to the accompanying drawings.

### BRIEF DESCRIPTION OF THE DRAWINGS

FIG. 1A illustrates particle distribution on the surface of the in-situ doped polysilicon layer after this layer is deposited for 4 hours;

FIG. 1B illustrates particle distribution on the surface of the in-situ doped polysilicon layer after this layer is deposited for 8 hours;

FIG. 1C illustrates particle distribution on the surface of the in-situ doped polysilicon layer after this layer is deposited for 24 hours;

FIG. 1D illustrates particle distribution on the surface of the in-situ doped polysilicon layer after this layer is deposited for 48 hours;

FIG. 2 is a flow chart of a method of manufacturing a semiconductor device according to a preferred embodiment of the present invention;

FIG. 3A illustrates a substrate, an insulation layer and a semiconductor based layer according to the preferred embodiment of the present invention;

FIG. 3B illustrates a doped layer formed on the surface of the semiconductor based layer in FIG. 3A;

FIG. 3C illustrates the dopant diffusing into the semiconductor based layer in FIG. 3B;

FIG. 3D illustrates semiconductor layer in FIG. 3C after the clean process;

FIG. 3E illustrates the substrate in FIG. 3D after being doped;

FIG. 3F illustrates the insulation layer in FIG. 3E after being patterned;

FIG. 4A shows particle distribution on the surface of the semiconductor layer after the semiconductor layer being formed for a week; and

FIG. 4B shows particle distribution on the surface of the semiconductor layer after the surface is cleaned according to the method for surface modification of the present embodiment.

FIG. 5 illustrates a diagram of the variation of the particle numbers in accordance with time.

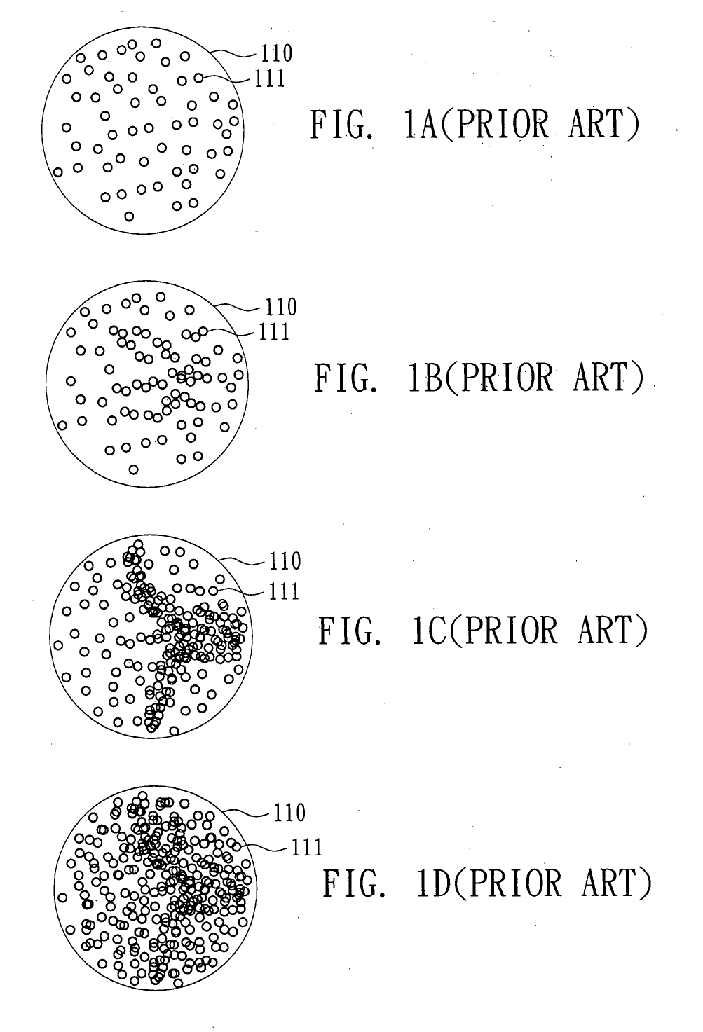

### DETAILED DESCRIPTION OF THE INVENTION

A preferred embodiment is provided as follow to illustrate the present invention. The embodiment is used as an example, and the present invention is not limited thereto. Moreover, unnecessary elements are omitted to clearly show the features of the invention.

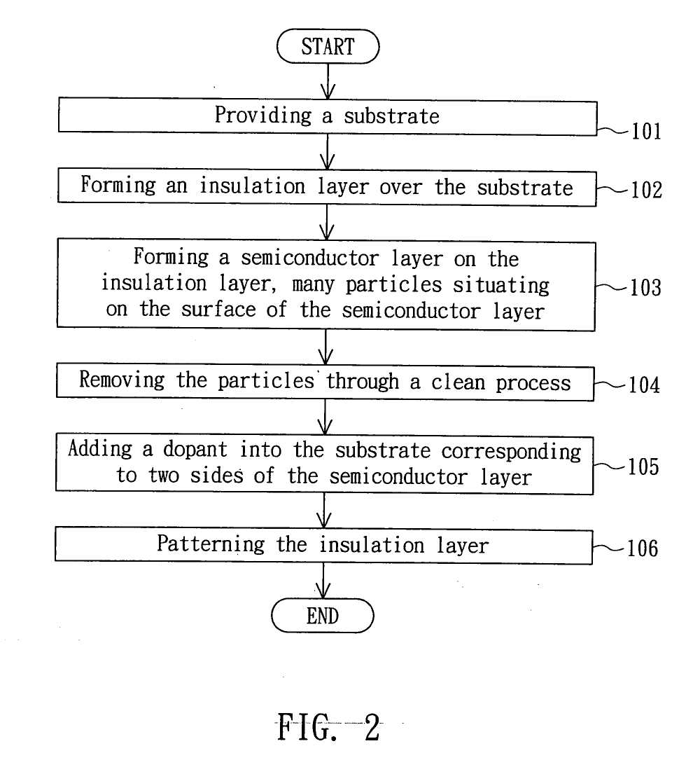

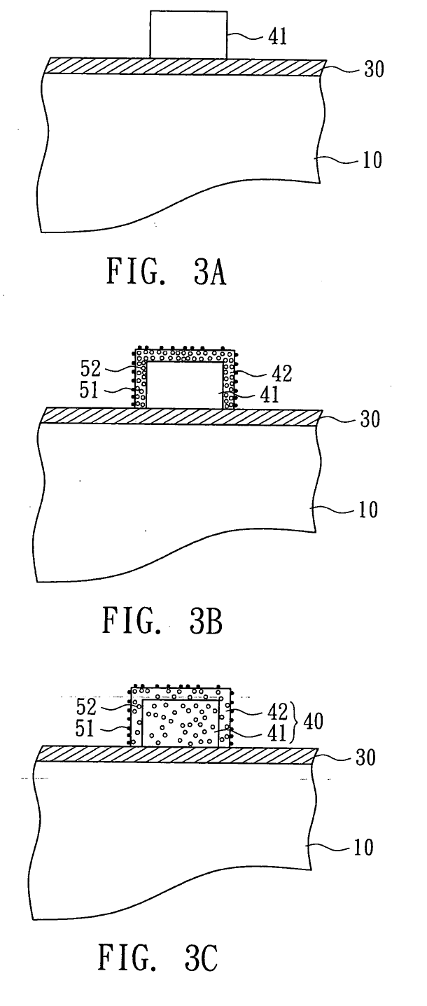

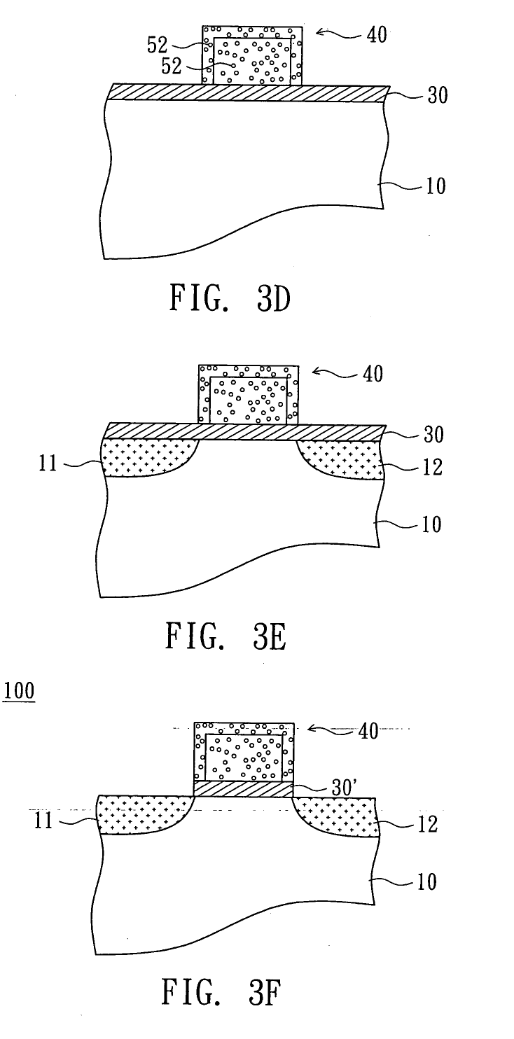

Please refer to FIG. 2 and FIGS. 3A˜3F at the same time. FIG. 2 is a flow chart of a method of manufacturing a semiconductor device according to the preferred embodiment of the present invention. FIG. 3A illustrates a substrate, an insulation layer and a semiconductor based layer according to the preferred embodiment of the present invention. FIG. 3B illustrates a doped layer formed on the surface of the semiconductor based layer in FIG. 3A. FIG. 3C illustrates the dopant diffusing into the semiconductor based layer in FIG. 3B. FIG. 3D illustrates semiconductor layer in FIG. 3C after the clean process. FIG. 3E illustrates the substrate in FIG. 3D after being doped. FIG. 3F illustrates the insulation layer in FIG. 3E after being patterned.

The method of manufacturing a semiconductor device includes following steps. First, in step 101, a substrate 10 is provided. Then, in step 102, an insulation layer 30 is formed on the substrate 10.

Afterwards, a semiconductor layer is formed on the insulation layer 30 in step 103. The method of forming the semiconductor layer includes the following steps for example. First, a semiconductor based layer 41 covering part of the insulation layer 30 is deposited on the insulation layer 30, as shown in FIG. 3A. Then, a doped layer 42, such as an in-situ doped polysilicon layer, covering the surface of the semiconductor based layer 41 is formed, as shown in FIG. 3B. The doped layer 42 includes a high concentration dopant 52. After the doped layer 42 is formed, the method of forming the silicon layer further proceeds the step of adding the dopant 52, as shown in FIG. 3C. In the present embodiment, the dopant 52 is added into the semiconductor based layer 41 from the doped layer 42 through high temperature diffusion doping for example. After the dopant 52 is added, the semiconductor based layer 41 and the doped layer 42 construct the semiconductor layer 40 as a whole.

After the semiconductor layer 40 is formed, many particles 51 are separated out on its surface. Therefore, the method of manufacturing the semiconductor device further conducts the step of removing the particles 51. In step 104 of FIG. 2, the surface of the semiconductor layer 40 is modified through a clean process for removing the particles 51, as shown in FIG. 3D. First, an organic matter remover including sulfuric acid (H₂SO₄) and hydrogen peroxide (H₂O₂) is used for removing the organic pollutant on the surface of the semiconductor layer 40. As a result, the surface of the semiconductor layer 40 is less hydrophobic, and the clean steps thereafter can be proceeded more efficiently. After that, the silicon layer 40 is optionally exposed to an oxide remover that includes hydrogen fluoride de-ionized solution. Then, the semiconductor layer 40 is exposed to a first peroxide mixture solution and a second peroxide mixture solution sequentially. In the present embodiment, the first peroxide mixture solution includes ammonia (NH₄OH), hydrogen peroxide and de-ionized water, and the second peroxide mixture solution includes hydrochloric acid (HCl), hydrogen peroxide and de-ionized water. A portion of the semiconductor layer 40 is oxidized by hydrogen peroxide, and then the oxidized semiconductor layer 40 is removed by ammonia. As a result, the particles 51 are removed from the surface of the semiconductor layer 40. The hydrochloric acid in the second peroxide mixture solution removes alkali metal ions on the surface of the semiconductor layer 40 to further improve the surface quality. Moreover, the semiconductor layer 40 is purged by water. After the clean process, the particles 51 on the surface of the semiconductor layer 40 are removed, and the semiconductor layer 40 remains clean for about twelve hours. Therefore, it is ensured that there is no particle on the surface of the semiconductor layer 40 during the following manufacturing process.

After that, as shown in step 105 and FIG. 3E, another dopant, preferably same type as the dopant 51, is added into the substrate 10 corresponding to two sides of the semiconductor layer 40 to form a source region 11 and a drain region 12 of the semiconductor device. In the present embodiment, the insulation layer 30 is preferably made of silicon dioxide (SiO₂). As for the method of doping the substrate 10, an ion implantation process is applied for instance. The insulation layer 30 is used as a buffer layer while doping the substrate 10.

Then, in step 106, the insulation layer 30 is patterned. The width of the patterned insulation layer 30′ is substantially equal to that of the semiconductor layer 40, as shown in FIG. 3F. As the patterning step finishes, the semiconductor device 100 according to the preferred embodiment of the present invention is completed. In the present embodiment, the semiconductor device 100 is exemplified by a MOS transistor. The semiconductor layer 40 is the gate electrode of the semiconductor device 100. In the present embodiment, the semiconductor layer 40 is made of doped polysilicon, yet the semiconductor layer 40 can be simply made of polysilicon either. However, any one who is skilled in the technology of the art can understand that the material of the semiconductor layer 40 can also be silicon, germanium or combination thereof. The insulation layer 30′ preferably is made of silicon dioxide (SiO₂).

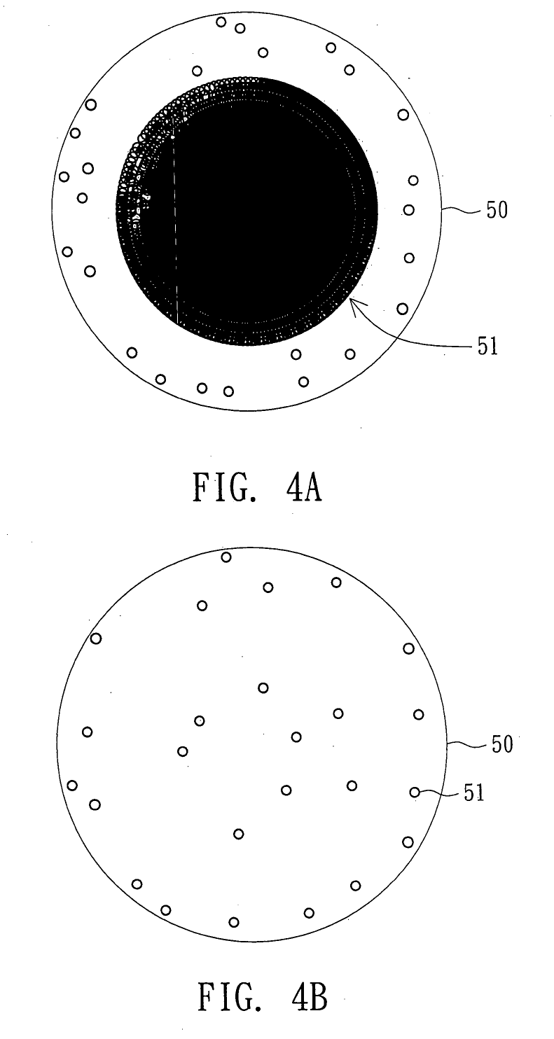

Refer to FIG. 4A and FIG. 4B; FIG. 4A shows particle distribution on the surface of the semiconductor layer after the semiconductor layer being formed for a week; FIG. 4B shows particle distribution on the surface of the semiconductor layer after the surface is cleaned according to the method for surface modification of the present embodiment. In the present embodiment, the surface modification of the semiconductor layer 40 is conducted by the organic matter remover, the first peroxide mixture solution and the second peroxide mixture solution. After the semiconductor layer 40 is deposited for one week, the number of the particles on the surface of the semiconductor layer 40 is measured by a measuring machine. Within the capacity of the measuring machine, the particles 51 have covered the entire surface of the semiconductor layer 40, i.e. the dark circle area in FIG. 4A. And after the surface modification via the method of the present embodiment, the number of the particles 51 is significantly decreased, as shown in FIG. 4B.

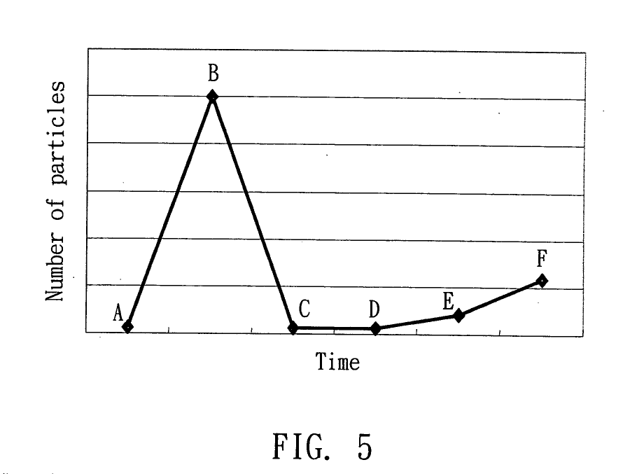

The effect of the method of the present embodiment for surface modification of the semiconductor layer 40 can be expressed by way of the changes in the particle 51 numbers in accordance with time. Please refer to FIG. 5, a diagram of the variation of the particle numbers in accordance with time is illustrated. Point A indicates the number of the particles 51 right after the semiconductor layer 40 is deposited. Point B indicates the number of the particles 51 after the semiconductor layer 40 is deposited for 12 hours. Point C indicates the number of particles 51 right after surface modification of the semiconductor layer 40. Point D, point E and point F respectively indicates the number of particles 51 after surface modification of the semiconductor layer 40 for 12 hours, 24 hours and 36 hours. As shown in FIG. 5, the number of the particles 51 on the surface of the semiconductor layer 40 is decreased significantly through the method for surface modification according to the preferred embodiment of the present invention, and it is another 12 hours (indicated by point D in FIG. 5) that the number of the particles 51 begins to rise again. Therefore, the problems regarding to the quality degradation of the semiconductor devices caused by the particles 51 are resolved.

In the method for surface modification of a semiconductor layer and the method of manufacturing a semiconductor device according to the preferred embodiment of the invention, the organic matter remover, the first peroxide mixture solution and the second peroxide mixture solution are used for cleaning the surface of the semiconductor layer. The methods have the feature of simple cleaning steps. Regardless of the forming process of the semiconductor layer, the method for surface modification of the semiconductor layer can effectively remove the particles separating out on the surface of the semiconductor layer. Therefore, the following manufacturing steps of the semiconductor device, such as forming a metal silicide layer or a metallization process, can maintain good electrical characteristics. In other words, the particle issue like performance lowering caused by current leakage of the gate in a MOS transistor or in a memory device is resolved effectively, thus stabilizing the threshold voltage of the semiconductor device. Then the yield rate of the product is increased, and the manufacturing cost is lowered accordingly. Moreover, the reliability of the product is improved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for surface modification of a semiconductor layer, the method comprising:
providing a semiconductor layer with a plurality of particles on the surface of the semiconductor layer; and
removing the particles through a clean process, the process comprising:
exposing the semiconductor layer to an organic matter remover;
exposing the semiconductor layer to a first peroxide mixture solution; and
exposing the semiconductor layer to a second peroxide mixture solution.

2. The method according to claim 1, wherein the semiconductor layer is provided by forming a polysilicon layer or a doped polysilicon layer.

3. The method according to claim 1, wherein the semiconductor layer is made of silicon, germanium or combination thereof.

4. The method according to claim 1, wherein the first peroxide mixture solution comprises ammonia (NH₄OH), hydrogen peroxide (H₂O₂) and de-ionized water.

5. The method according to claim 4, wherein the second peroxide mixture solution comprises hydrochloric acid (HCl), hydrogen peroxide and de-ionized water.

6. The method according to claim 1, wherein after the step of exposing the semiconductor layer to the second peroxide mixture solution, the method further comprises:
purging the semiconductor layer by water.

7. The method according to claim 1, wherein the organic matter remover comprises sulfuric acid (H₂SO₄) and hydrogen peroxide (H₂O₂).

8. The method according to claim 1, wherein after the step of exposing the semiconductor layer to the organic matter remover, the method further comprises:
exposing the semiconductor layer to an oxide remover.

9. The method according to claim 8, wherein the oxide remover comprises hydrogen fluoride de-ionized solution.

10. A method of manufacturing a semiconductor device, the method comprising:
providing a substrate;
forming an insulation layer over the substrate;
forming a semiconductor layer on the insulation layer, wherein a plurality of particles situate on the surface of the semiconductor layer;
removing the particles through a clean process, the process comprising:
exposing the semiconductor layer to an organic matter remover;
exposing the semiconductor layer to a first peroxide mixture solution; and
exposing the semiconductor layer to a second peroxide mixture solution.

11. The method according to claim 10, wherein after the step of exposing the semiconductor layer to the second peroxide mixture solution, the method further comprises:
purging the semiconductor layer by water.

12. The method according to claim 10, wherein after the step of exposing the semiconductor layer to the organic matter remover, the method further comprises:
exposing the semiconductor layer to an oxide remover.

13. The method according to claim 12, wherein the oxide remover comprises hydrogen fluoride de-ionized solution.

14. The method according to claim 10, wherein the organic matter remover comprises sulfuric acid and hydrogen peroxide.

15. The method according to claim 10, wherein the first peroxide mixture solution comprises ammonia, hydrogen peroxide and de-ionized water.

16. The method according to claim 15, wherein the second peroxide mixture solution comprises hydrochloric acid, hydrogen peroxide and de-ionized water.

17. The method according to claim 10, wherein the method further comprises:
adding a dopant into the substrate corresponding to two sides of the of the electrode layer.

18. The method according to claim 17, wherein after the step of adding the dopant, the method further comprises:
patterning the insulation layer, such that the insulation layer and the semiconductor layer have substantially the same width.

19. The method according to claim 10, wherein the semiconductor layer is provided by forming a polysilicon layer or a doped polysilicon layer.

20. The method according to claim 19, wherein the insulation layer is made of silicon dioxide (SiO₂).

21. The method according to claim 10, wherein the semiconductor layer is made of silicon, germanium and combination thereof.

22. The method according to claim 10, wherein the step of forming the semiconductor layer further comprises:
forming a semiconductor based layer covering part of the insulation layer;
adding a dopant into the semiconductor based layer from a doped layer by diffusion doping.
